(19) United States
(12) Patent Application Publication
(10) Pub. No.: US 2010/0037940 A1
(43) Pub. Date: Feb. 18, 2010

(54) STACKED SOLAR CELL

(76) Inventors: Mi-Hwa Lim, Seocheon-gun (KR); Czang-Ho Lee, Suwon-si (KR); Joon-Young Seo, Seoul (KR); Myung-Hun Shin, Suwon-si (KR); Min-Seok Oh, Yongin-si (KR); Byoung-Kyu Lee, Cheonan-si (KR); Yuk-Hyun Nam, Goyang-si (KR); Seung-Jae Jung, Seoul (KR)

Correspondence Address: F. CHAU & ASSOCIATES, LLC, 130 WOODBURY ROAD, WOODBURY, NY, 11797, US

(21) Appl. No.: 12/468,444

(22) Filed: May 19, 2009

(30) Foreign Application Priority Data
Aug. 18, 2008 (KR) 10-2008-0080480

(51) Int. Cl. H01L 31/00

(52) U.S. Cl. 136/255; 136/258

(57) ABSTRACT

A solar cell including a first semiconductor layer formed by sequentially stacking a positive (P) layer, an intrinsic (I) layer and a negative (N) layer, wherein the P layer comprises amorphous silicon carbide and at least one of the I and N layers comprises micro-crystalline silicon.

### CROSS-REFERENCE TO RELATED APPLICATION

This application claims priority to Korean Patent Application No. 10-2008-0080480 filed in the Korean Intellectual Property Office on Aug. 18, 2008, the disclosure of which is incorporated by reference herein in its entirety.

### BACKGROUND OF THE INVENTION

1. Technical Field

The present invention relates to a stacked solar cell formed of junctions with different phases.

2. Discussion of the Related Art

A solar cell is a device that converts solar energy into electricity. In general, a solar cell is a diode formed of a PN junction. A PN junction is formed of positive (P)-type and negative (N)-type semiconductors.

A solar cell that uses silicon as a light absorbing layer may be classified as a crystalline silicon solar cell or a thin film solar cell. A crystalline silicon solar cell may be classified according to its crystallinity (e.g., single crystal or polycrystalline). A thin film solar cell may be classified according to its photovoltaic material (e.g., crystalline or amorphous).

A thin film solar cell may be formed by coating a film onto a substrate made of thin glass or plastic. In a thin film solar cell, due to a characteristic of the thin film, the diffusion distance of carriers is short as compared to that of a crystalline silicon solar cell. In addition, if the thin film solar cell is fabricated with only the PN junction, the collection efficiency of electron-hole pairs generated by sunlight is lowered. Therefore, a thin film solar cell may be made with a positive-intrinsic-negative (PIN) structure where an intrinsic semiconductor-based light absorbing layer with high light absorption is interposed between the P-type and N-type semiconductors.

A thin film solar cell may have a structure where a front transparent conductive film, a PIN layer, and a rear reflective electrode layer are sequentially deposited on a substrate. In this structure, since the light absorbing layer is depleted due to the overlying P and underlying N layers, which have high doping concentrations, an electric field is generated therein. As a result, when carriers are generated in the light absorbing layer by sunlight, electrons are collected at the N layer and holes are collected at the P layer by an internal electric field drift, thereby generating electric currents.

A thin film solar cell using amorphous silicon (a-Si:H) or micro-crystalline silicon (mc-Si:H) may use a thin film having a thickness of less than several microns as a light absorbing layer. However, high efficiency may not be achieved with a single PIN structure, since silicon has a low light absorption coefficient. Therefore, a stacked solar cell that is formed by double or triple stacking amorphous silicon (a-Si:H) and micro-crystalline silicon (mc-Si:H) in a PIN structure is generally used. In the stacked solar cell, an open circuit voltage can be increased by connecting the solar cells in series, and a conversion efficiency with respect to incident light can be improved. However, in the stacked solar cell, an interface between stacked layers causes recombination, thereby decreasing light efficiency.

Accordingly, there is a need for a technique of providing a stacked solar cell with improved light efficiency.

### SUMMARY OF THE INVENTION

A solar cell according to an exemplary embodiment of the present invention includes a first semiconductor layer formed by sequentially stacking a positive (P) layer, an intrinsic (I) layer, and a negative (N) layer, wherein the P layer comprises amorphous silicon carbide and at least one of the I and N layers comprises micro-crystalline silicon.

The solar cell further includes a second semiconductor layer adjacent to the first semiconductor layer, wherein the second semiconductor layer comprises a P layer, an I layer, and an N layer, and wherein at least one of the P, I, and N layers of the second semiconductor layer comprises amorphous silicon.

The solar cell further includes a third semiconductor layer formed between the first and second semiconductor layers, wherein the third semiconductor layer is formed by sequentially stacking a P layer, an I layer and an N layer. The I layer and the N layer of the third semiconductor layer comprise amorphous silicon germanium (a-SiGe). The I layer of the first semiconductor layer includes an incubation layer adjacent to a top surface of the P layer of the first semiconductor layer.

The incubation layer includes amorphous silicon.

The second semiconductor layer may be disposed closer to a light incident side of the solar cell than the first semiconductor layer.

The I layer of the first semiconductor layer has different degrees of crystallization in a vertical direction.

The P, I, and N layers of the second semiconductor layer are sequentially stacked on a substrate, and the solar cell further includes a transparent conductive film formed between the substrate and the second semiconductor layer.

The solar cell further includes a rear electrode disposed on the first semiconductor layer.

A stacked solar cell according to an exemplary embodiment of the present invention includes a substrate, a transparent conductive film formed on the substrate, a plurality of semiconductor layers each including a P layer, an I layer, and an N layer, wherein the plurality of semiconductor layers are sequentially stacked on the transparent conductive film, and a rear electrode disposed on a semiconductor layer disposed farthest from the transparent conductive film. A first semiconductor layer has an I layer comprising micro-crystalline silicon and a second semiconductor layer has an I layer comprising amorphous silicon. The first semiconductor layer and the second semiconductor layer are adjacent to each other, and a P layer of the first semiconductor layer includes amorphous silicon carbide.

An N layer of the second semiconductor layer comprises amorphous silicon.

The second semiconductor layer is formed closer to a light incident side of the stacked solar cell than the first semiconductor layer.

The stacked solar cell further includes a third semiconductor layer disposed between the first and second semiconductor layers, wherein the third semiconductor layer is formed by sequentially stacking a P layer, an I layer and an N layer. The I layer and the N layer of the third semiconductor layer comprise amorphous silicon germanium (a-SiGe).

A P layer of the second semiconductor layer comprises boron doped amorphous silicon (a-Si:H) or amorphous silicon carbide (a-SiC:H)

An N layer of the first semiconductor layer comprises micro-crystalline silicon or amorphous silicon.

The I layer of the first semiconductor layer includes an incubation layer that is adjacent to a top surface of the P layer of the first semiconductor layer.

The incubation layer is generated when growing a thin film. A stacked solar cell according to an exemplary embodiment of the present invention includes a first semiconductor layer formed by sequentially stacking a P layer, an I layer and an N layer; and a second semiconductor layer formed by sequentially stacking a P layer, an I layer and an N layer, wherein the first semiconductor layer is disposed on the second semiconductor layer, and the P layer of the first semiconductor layer that forms an interface with the N layer of the second semiconductor layer comprises amorphous silicon carbide.

The I layer of the first semiconductor layer comprises micro-crystalline silicon.

### BRIEF DESCRIPTION OF THE DRAWINGS

FIG. 1 is a graph showing characteristics of a positive-intrinsic-negative (PIN) layer formed of amorphous silicon and a PIN layer formed of micro-crystalline silicon.

FIG. 2 is a cross-sectional view of a stacked solar cell according to an exemplary embodiment of the present invention.

FIG. 3 is a transmission electrode microscope (TEM) photo of a cross-section of micro-crystalline silicon thin film deposited on zinc oxide (ZnO).

FIG. 4 is a cross-sectional view of a stacked solar cell according to an exemplary embodiment of the present invention.

### DETAILED DESCRIPTION OF EXEMPLARY EMBODIMENTS

Exemplary embodiments of the present invention will be described more fully hereinafter with reference to the accompanying drawings. However, the present invention may be embodied in many different forms and should not be construed as limited to the exemplary embodiments described herein.

In the drawings, the thicknesses of layers and regions may be exaggerated for clarity. It is to be noted that when a layer is referred to as being “on” another layer or substrate, it can be directly formed on the other layer or substrate or it can be formed on the other layer or substrate with a third layer or other additional layers interposed therebetween. Like elements are denoted by like reference numerals throughout the specification.

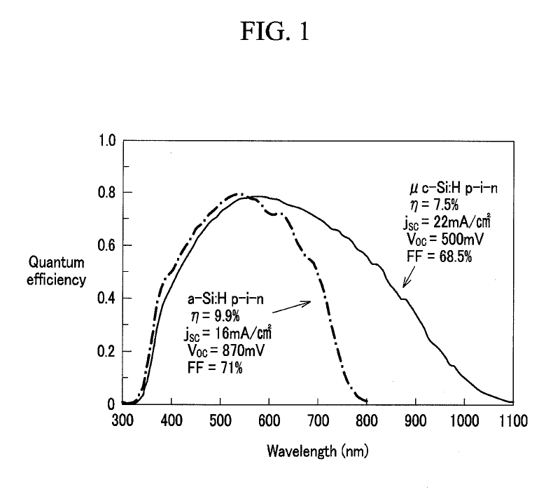

FIG. 1 is a graph showing characteristics of a positive-intrinsic-negative (PIN) layer formed of amorphous silicon and a PIN layer formed of micro-crystalline silicon. FIG. 1 was published in a paper entitled, “Potential of Amorphous Silicon for Solar Cells”, by Rech, B. et al., (Applied Physics A: Materials Science & Processing, vol. 69, no. 2, p. 164 (1999)).

Referring to FIG. 1, the graph shows a number of electron-hole pairs generated at particular quantum efficiency values. A light absorbing layer formed of amorphous silicon absorbs only a short wavelength, and a light absorbing layer formed of micro-crystalline silicon absorbs short and long wavelengths within a wider light-absorbing wavelength band.

In a stacked solar cell, an open circuit voltage (Voc) of a PIN layer formed of micro-crystalline silicon is lower than that of a PIN layer formed of amorphous silicon. Short current density (Isc) is higher in the PIN layer formed of micro-crystalline silicon than in the PIN layer formed of amorphous silicon, but the open circuit voltage Voc of the PIN layer is about 0.5V, which is lower than the open circuit voltage Voc of the PIN layer, which is about 0.87V. Such a low open circuit voltage reduces the light efficiency of the entire stacked solar cell.

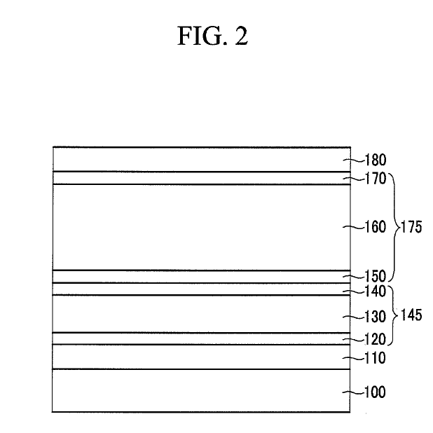

FIG. 2 is a cross-sectional view of a stacked solar cell according to an exemplary embodiment of the present invention.

Referring to FIG. 2, a solar cell according to an exemplary embodiment of the present invention includes a transparent conductive film 110 stacked on a substrate 100. The transparent conductive film 110 may be formed of tin oxide (SnO₂), aluminum doped zinc oxide (ZnO:Al), or boron doped zinc oxide (ZnO:B). An upper plane of the transparent conductive film 110 may be textured.

The texturing is performed for the purpose of increasing an amount of light absorbed inside the solar cell by reducing the reflection of light from the solar cell's surface. The texture of the upper plane of the transparent conductive film 110 is formed in a pyramid structure with a size of about 10 μm by an etching process.

Since a diffusion distance of electron-hole pairs in a thin film type of silicon solar cell is short as compared to a crystalline silicon PN junction solar cell that is operated by diffusion of electron-hole pairs generated by sunlight, a light absorbing layer and an intrinsic Si layer that are capable of simultaneously generating an internal electric field can be inserted between a P layer and an N layer. The intrinsic semiconductor layer may correspond to an I layer 130 in the present exemplary embodiment.

In the solar cell according to the present exemplary embodiment, a P layer 120, the I layer 130, and an N layer 140 are sequentially stacked on the transparent conductive film 110. The P layer 120, the I layer 130, and the N layer 140 can be deposited by a plasma enhanced chemical vapor deposition (PECVD) method.

When electron-hole pairs are generated in the I layer 130, which is a light absorbing layer, by sunlight, electrons are collected in the N layer 140 and holes are collected in the P layer 120 by a drift of the internal electric field, thereby generating electric currents.

The P layer 120 may be formed from either one of boron doped amorphous silicon (a-Si:H) and amorphous silicon carbide (a-SiC:H). The I layer 130, which is a light absorbing layer, and the N layer 140 may be formed from amorphous silicon (a-Si:H). A first semiconductor layer 145 including the P layer 120, the I layer 130, and the N layer 140 substantially absorbs light of a short wavelength because the light absorbing layers are formed of amorphous silicon (a-Si:H).

To form a tandem structure in the solar cell according to the present exemplary embodiment, a second semiconductor layer 175 including a P layer 150, an I layer 160, and an N layer 170 is formed on the N layer 140 of the first semiconductor layer 145. The I layer 160, which is a light absorbing layer of the second semiconductor layer 175, may be formed of micro-crystalline silicon (mc-Si:H). A rear electrode 180 is formed on the second semiconductor layer 175.

In a solar cell with a like tandem structure, a doped layer adjacent to the light absorbing layer of amorphous silicon may be formed of an amorphous silicon layer, and a doped layer adjacent to the light absorbing layer of micro-crystalline silicon may be formed of a micro-crystalline silicon layer.

Such a stacked solar cell has a high open circuit voltage Voc for high light efficiency, and recombination in the solar cell can be reduced to obtain a high fill factor and a high short current density Isc. If a process for generating a pair of an electron and a hole or a process for exciting electrons from a valance band to a conduction band in a semiconductor is defined by the term “generation”, the term “recombination” refers to a process in which the electrons move from a conduction band to a valance band so that one pair of an electron and a hole is eliminated, for example.

In addition, since an interface between the PIN layers (semiconductor layers) is a junction of different phases of amorphous and micro-crystalline, the interface property is not as good as an interface property of a homo-junction.

Therefore, the solar cell according to the present exemplary embodiment provides a structure for improving light efficiency by increasing the open circuit voltage Voc of the stacked solar cell and for improving the interface property.

For example, referring back to FIG. 2, the first semiconductor layer 145 and the second semiconductor layer 175 adjacent to the first semiconductor layer 145 form a stacked solar cell. In this case, the P layer 150 of the second semiconductor layer 175 that forms an interface with the N layer 140 of the first semiconductor layer 145 is formed of amorphous silicon carbide (a-SiC:H). The amorphous silicon carbide has a higher band gap as compared to micro-crystalline silicon so that the open circuit voltage Voc can be increased, and has the same amorphous phase as the N layer 140 of the first semiconductor layer 145 so that the interface property between the first and second semiconductor layers 145 and 175 can be improved. As a result, light efficiency of the stacked solar cell can be increased.

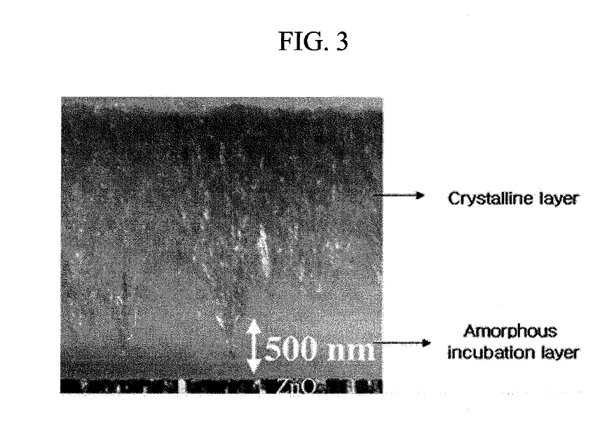

When the I layer 160, which is the light absorbing layer of the second semiconductor layer 175, is formed of micro-crystalline silicon, an incubation layer of an amorphous phase is generated upon the growth of a thin film. This is shown by the transmission electrode microscope (TEM) photo shown in FIG. 3.

FIG. 3 is a TEM photo of a cross-section of micro-crystalline silicon thin film deposited on ZnO. The photo of FIG. 3 was published in a paper entitled, “Material and Solar Cell Research in Microcrystalline Silicon”, by Shah, A. V. et al., (Solar Energy Materials & Solar Cells, vol. 78, no. 1, p. 474 (2003)).

Referring to FIG. 3, when the micro-crystalline silicon thin film is deposited on ZnO, it grows into an amorphous structure in an early stage, and then, it grows into a micro-crystalline structure. A micro-crystalline solar cell can have good characteristics when using a light absorbing layer in which the crystallization fraction of a micro-crystalline thin film is about 60%. Therefore, in the second semiconductor layer 175, the interface property between the P layer 150 and the I layer 160, which is the light absorbing layer formed of micro-crystalline silicon, can be further improved when the P layer 150 has an amorphous phase.

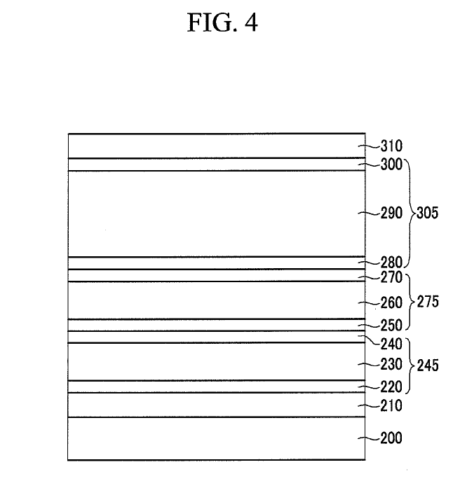

FIG. 4 is a cross-sectional view of a stacked solar cell according to an exemplary embodiment of the present invention.

Referring to FIG. 4, a solar cell according to the exemplary embodiment of the present invention includes a transparent conductive film 210 stacked on a substrate 200. The transparent conductive film 210 may be formed of SnO₂, ZnO:Al, or ZnO:B. An upper plane of the transparent conductive film 210 may be textured.

Since a diffusion distance of electron-hole pairs in a thin film type of silicon solar cell is short as compared to a crystalline silicon PN junction solar cell that is operated by diffusion of electron-hole pairs generated by sunlight, a light absorbing layer and an intrinsic Si layer that are capable of simultaneously generating an internal electric field can be inserted between a P layer and an N layer. The intrinsic semiconductor layer may correspond to an I layer 230 in the present exemplary embodiment.

In the solar cell according to the present exemplary embodiment, a P layer 220, the I layer 230, and an N layer 240 are sequentially stacked on the transparent conductive film 210. The P layer 220, the I layer 230, and the N layer 240 can be deposited by a plasma enhanced chemical vapor deposition (PECVD) method.

The P layer 220 may be formed from either one of boron doped amorphous silicon (a-Si:H) and amorphous silicon carbide (a-SiC:H). The I layer 230, which is a light absorbing layer, and the N layer 240 may be formed from amorphous silicon (a-Si:H). A first semiconductor layer 245 including the P layer 220, the I layer 230, and the N layer 240 substantially absorbs light of a short wavelength because the light absorbing layers are formed of amorphous silicon (a-Si:H).

In the solar cell according to the present exemplary embodiment, a second semiconductor layer 275 including a P layer 250, an I layer 260, and an N layer 270 is formed on the N layer 240, and a third semiconductor layer 305 including a P layer 280, an I layer 290, and an N layer 300 is formed on the second semiconductor layer 275 to form a triple-junction structure in which PIN layers are sequentially stacked in a PIN/PIN/PIN order. When the semiconductor layers 245, 275, and 305 are formed in a multi-layered structure, a light absorbing band can be widened. A rear electrode 310 is formed on the third semiconductor layer 305.

The I layer 260, which is a light absorbing layer of the second semiconductor layer 275, may be formed of amorphous silicon germanium (a-SiGe). In general, a doping layer adjacent to a light absorbing layer of amorphous silicon uses an amorphous silicon layer, and a doping layer adjacent to a light absorbing layer of micro-crystalline silicon uses a micro-crystalline silicon layer. Therefore, the N layer 270 of the second semiconductor layer 275 may be formed of amorphous silicon germanium (a-SiGe). The I layer 290, which is a light absorbing layer of the third semiconductor layer 305, may be formed of micro-crystalline silicon (mc-Si:H).

The P layer 280 of the third semiconductor layer 305, which forms an interface with the N layer 270 of the second semiconductor layer 275, is formed of amorphous silicon carbide (a-SiC:H). The amorphous silicon carbide has a higher band gap as compared to micro-crystalline silicon so that the open circuit voltage Voc can be increased, and has the same amorphous silicon as the N layer 270 of the second semiconductor layer 275 so that the interface property between the second semiconductor 275 and the third semiconductor 305 can be improved. As a result, light efficiency of the stacked solar cell can be increased.

When the I layer 290, which is a light absorbing layer of the third semiconductor layer 305, is formed of micro-crystalline silicon, an incubation layer of an amorphous phase is generated upon the growth of a thin film. When a micro-crystalline silicon thin film is deposited, it grows into an amorphous structure in an early stage and, then, it grows into a micro-crystalline structure. A micro-crystalline solar cell can have good characteristics when using a light absorbing layer in which the crystallization fraction of a micro-crystalline thin film is about 60%.

Therefore, in the third semiconductor layer 305, the interface property between the P layer 280 and the I layer 290, which is the light absorbing layer formed of micro-crystalline silicon, can be further improved when the P layer 280 has an amorphous phase.

According to an exemplary embodiment of the present invention, a solar cell may have a multi-junction structure of four or more junctions.

According to an exemplary embodiment of the present invention, a P-type amorphous silicon carbide (a-SiC:H) layer is used instead of a P-type micro-crystalline silicon layer so that the open circuit voltage can be increased and the interface property can be improved. Therefore, light efficiency of a stacked solar cell can be increased.

While the present invention has been described in detail with reference to the exemplary embodiments, those skilled in the art will appreciate that various modifications and substitutions can be made thereto without departing from the spirit and scope of the present invention as set forth in the appended claims.

What is claimed is:

1. A solar cell, comprising:
a first semiconductor layer formed by sequentially stacking a positive (P) layer, an intrinsic (I) layer, and a negative (N) layer,
wherein the P layer comprises amorphous silicon carbide and at least one of the I and N layers comprises micro-crystalline silicon.

2. The solar cell of claim 1, further comprising:
a second semiconductor layer adjacent to the first semiconductor layer, wherein the second semiconductor layer comprises a P layer, an I layer, and an N layer, and
wherein at least one of the P, I, and N layers of the second semiconductor layer comprises amorphous silicon.

3. The solar cell of claim 2, wherein the second semiconductor layer is disposed closer to a light incident side of the solar cell than the first semiconductor layer.

4. The solar cell of claim 3, further comprising:
a third semiconductor layer formed between the first and second semiconductor layers, wherein the third semiconductor layer is formed by sequentially stacking a P layer, an I layer and an N layer, and
wherein the I layer and the N layer of the third semiconductor layer comprise amorphous silicon germanium (a-SiGe).

5. The solar cell of claim 2, wherein the I layer of the first semiconductor layer comprises an incubation layer adjacent to a top surface of the P layer of the first semiconductor layer.

6. The solar cell of claim 5, wherein the incubation layer comprises amorphous silicon.

7. The solar cell of claim 6, wherein the second semiconductor layer is disposed closer to a light incident side of the solar cell than the first semiconductor layer.

8. The solar cell of claim 2, wherein the I layer of the first semiconductor layer has different degrees of crystallization in a vertical direction.

9. The solar cell of claim 2, wherein the P, I, and N layers of the second semiconductor layer are sequentially stacked on a substrate, and the solar cell further comprises a transparent conductive film formed between the substrate and the second semiconductor layer.

10. The solar cell of claim 1, further comprising:
a rear electrode disposed on the first semiconductor layer.

11. A stacked solar cell, comprising:
a substrate;
a transparent conductive film formed on the substrate;
a plurality of semiconductor layers each including a positive (P) layer, an intrinsic (I) layer, and a negative (N) layer, wherein the plurality of semiconductor layers are sequentially stacked on the transparent conductive film; and
a rear electrode disposed on a semiconductor layer disposed farthest from the transparent conductive film,
wherein a first semiconductor layer has an I layer comprising micro-crystalline silicon and a second semiconductor layer has an I layer comprising amorphous silicon, the first semiconductor layer and the second semiconductor layer are adjacent to each other, and a P layer of the first semiconductor layer comprises amorphous silicon carbide.

12. The stacked solar cell of claim 11, wherein the second semiconductor layer is disposed closer to a light incident side of the stacked solar cell than the first semiconductor layer.

13. The stacked solar cell of claim 12, wherein an N layer of the second semiconductor layer comprises amorphous silicon.

14. The stacked solar cell of claim 13, further comprising:
a third semiconductor layer formed between the first and second semiconductor layers,
wherein the third semiconductor layer is formed by sequentially stacking a P layer, an I layer and an N layer, and
wherein the I layer and the N layer of the third semiconductor layer comprise amorphous silicon germanium (a-SiGe).

15. The stacked solar cell of claim 13, wherein a P layer of the second semiconductor layer comprises boron doped amorphous silicon (a-Si:H) or amorphous silicon carbide (a-SiC:H).

16. The stacked solar cell of claim 13, wherein an N layer of the first semiconductor layer comprises micro-crystalline silicon or amorphous silicon.

17. The stacked solar cell of claim 11, wherein the I layer of the first semiconductor layer comprises an incubation layer that is adjacent to a top surface of the P layer of the first semiconductor layer.

18. The stacked solar cell of claim 17, wherein the incubation layer is generated when growing a thin film.

19. A stacked solar cell, comprising:
a first semiconductor layer formed by sequentially stacking a positive (P) layer, an intrinsic (I) layer and a negative (N) layer; and
a second semiconductor layer formed by sequentially stacking a P layer, an I layer and an N layer,
wherein the first semiconductor layer is disposed on the second semiconductor layer, and the P layer of the first semiconductor layer that forms an interface with the N layer of the second semiconductor layer comprises amorphous silicon carbide.

20. The stacked solar cell of claim 19, wherein the I layer of the first semiconductor layer comprises micro-crystalline silicon.
